(19) United States
(12) Patent Application Publication
(10) Pub. No.: US 2008/0036079 A1
(43) Pub. Date: Feb. 14, 2008

(54) Conductive connection structure formed on the surface of circuit board and manufacturing method thereof

(75) Inventors: Chien-Chih Chen, Hsin-feng (TW); Wen-Hung Hu, Hsin-feng (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/812,407

(22) Filed: Jun. 19, 2007

(30) Foreign Application Priority Data
Aug. 14, 2006 (TW) 095129752

(51) Int. Cl. H01L 23/48; H01L 21/44

(52) U.S. Cl. 257/737; 438/614; 257/E21.476; 257/E23.01

(57) ABSTRACT

The conductive connection structure of the present invention comprises a circuit board, a plurality of conductive pads, a solder mask layer, an electroless plating copper layer, and an electroless plating adhesive layer. The manufacturing method comprises the following steps: providing the circuit board having a plurality of conductive pads thereon; forming the solder mask layer, the electroless plating copper layer, and the electroless plating adhesive layer respectively on the surface of the circuit board, and forming a solder bump on the electroless plating adhesive layer. By the assistance of the conductive connection structure and the manufacturing method thereof, cavity otherwise formed on the conductive pads can be prevented, and the solder bumps therefore are firmly fixed on the conductive pads. Moreover, the stress in the surface between the solder bump and the conductive pad can be reduced as the semiconductor chip and the circuit board are combined.

### BACKGROUND OF THE INVENTION

1. Field of the Invention

The present invention relates to a conductive connection structure formed on the surface of a circuit board and a manufacturing method thereof, and, more particularly, to a conductive connection structure having a secure connection to the solder bump by preventing cavity on the conductive pad due to metal atoms of the conductive pad diff-using to the solder bump that causes insecure connection of the solder bump, and a manufacturing method thereof.

2. Description of Related Art

The relentless progress in the electronics industry has lead to a focus on products being multi-functional and highly efficient. In order to satisfy high integration and miniaturization requirements of packaging semiconductor devices, providing circuit boards with the most active or passive components and connecting circuits thereon has gradually progressed from single layer toward multi-layers. However, due to the limited space of the circuit board, the usable circuit area has to be expanded by interlayer connection to fit requirements of the integrated circuit having high electronic density.

First, suitable chip carriers, e.g. substrates, of semiconductor devices are produced through a common manufacture of semiconductor devices. Then, the chip carrier undergoes processes of chip attachment, molding, and implanting etc. for assembling semiconductor devices.

In the conventional semiconductor device structure, semiconductor chips are attached on top of a substrate, and then are processed in wire bonding or connected with a flip chip. Further, a solder bump is deposited on the lateral of the substrate without semiconductor chips attached thereto so as to conduct external electronic elements. As shown in FIG. ID, an organic circuit board 101, a solder mask layer 102, a copper pad 103, an adhesive layer 105, and a solder bump 106 are included in conductive connection structure on the surface of conventional circuit boards. The manufacturing method thereof, as shown in FIGS. 1A and 1B, is first to provide a circuit board 101 on which a plurality of copper pads 103 are formed on the surface. Subsequently, a solder mask layer 102 is placed on the surface of the circuit board 101, wherein a plurality of first openings 104 corresponding to the surface of the copper pads 103 are formed on the solder mask layer 102. As shown in FIG IC, an adhesive layer 105 is formed on the surface of the copper pads 103 through electroless-plating. In FIG ID, a solder bump 106 is formed on the adhesive layer, and a conductive connection structure is completed on the surface of a conventional circuit board.

Although the aforementioned structure can achieve the objective of conduction, disadvantages of the manufacturing method for the conventional conductive connection structure still exist. As the copper pads 103 (conductive pads) are attached to the solder bump, wherein the solder bump comprises tin and other metals, copper atoms of the copper pads diffuse into the solder bump 106 to form an intermetallic compound due to potential difference between tin and copper. Then, the thickness of the copper pad 103 is decreased, and cavity is formed on contacting site between the tin and copper. According to experience in manufacture, the thickness of the copper pads is about 15 to 20 μm. The reaction of tin and copper forming the alloy causes the thickness of the copper pads to decrease about 7 to 9 μm. The formation of the cavity results in insecure connective structure between the solder bump and the copper pads and the deposited solder bump 106 tends to come off easily.

Therefore, it is desirable to provide a conductive connection structure preventing cavity on the conductive pad due to metal atoms of the conductive pad diffusing to the solder bump and the method thereof to mitigate and/or obviate the aforementioned problems.

### SUMMARY OF THE INVENTION

In view of the above conventional shortcomings, in the present invention, a conductive connection structure formed on the surface of a circuit board is provided and includes: a plurality of conductive pads which are formed on the surface of the circuit board; a solder mask layer which is formed on the surface of the circuit board and formed with a plurality of openings corresponding to the conductive pads to expose the surface thereof; an electroless plating copper layer which is formed on the surface of conductive pads; and an electroless plating adhesive layer which is formed on the surface of the electroless plating copper layer.

Thus, in the present invention, the conductive connection structure formed on the surface of the circuit board is provided to prevent cavity on the conductive pad due to metal atoms of the conductive pad diffusing to the solder bump, and to fix a solder bump firmly after reflow soldering without losing the solder bump.

According to the above conductive connection structure formed on the surface of the circuit board described in the present invention, the elements formed on the surface of the electroless plating adhesive layer is not limited, but is preferred to form the solder bump thereon.

According to the above conductive connection structure formed on the surface of the circuit board described in the present invention, the conductive pad is made of, but not limited to, preferably any one of the group consisting of copper, nickel, titanium, chromium, tin, and lead.

According to the above conductive connection structure formed on the surface of the circuit board described in the present invention, the solder mask layer is made of, but not limited to, preferably photosensitive resin.

According to the above conductive connection structure formed on the surface of the circuit board described in the present invention, the thickness of the electroless plating copper layer is not limited to, but preferably ranges between 7 and 15 μm.

According to the above conductive connection structure formed on the surface of the circuit board described in the present invention, the electroless plating adhesive layer is made of, but not limited to, preferably any one of the group consisting of tin, silver, nickel/gold, titanium, tungsten, titanium/tungsten, chromium, aluminum, or organic solderability preservatives (OSP).

According to the above conductive connection structure formed on the surface of the circuit board described in the present invention, the solder bump is made of, but not limited to, preferably any one of the group consisting of copper, tin, lead, silver, nickel, gold, and platinum.

Another object of the present invention is to provide a manufacturing method of a conductive connection structure formed on a circuit board. The manufacturing method includes the following steps: first, a) providing a circuit board with a solder mask layer and a plurality of conductive pads, wherein a plurality of openings are formed on the solder mask layer to expose the corresponding conductive pads; b) forming an electroless plating copper layer in the a plurality of openings on the surface of the conductive pads ; and c) forming an electroless plating adhesive layer on the surface of the electroless plating copper layer.

The electroless plating adhesive layer is firmly connected to the sequel solder bump whereby anti-oxidation of the conductive connection structure is improved. Subsequently, the manufacturing method further includes a step c1): after forming an electroless plating adhesive layer on the surface of the electroless plating copper layer, forming a solder bump on the electroless plating adhesive layer.

Therefore, in the present invention, the manufacturing method of the conductive connection structure formed on the circuit board is provided. The manufactured conductive connection structure is able to prevent metal atoms of the conductive pad from diffusing to solder forming cavity on the conductive pad, and further able to fix a solder bump firmly to form a solder ball after reflow soldering. Moreover, the stress in the surface between the solder bump and the conductive pad is reduced as the semiconductor chip and the printed circuit board are combined.

According to the above manufacturing method of conductive connection structure formed on the surface of the circuit board described in the present invention, the solder bump is formed, but not limited to, preferably through implanting, electroplating, or printing.

Other objects, advantages, and novel features of the invention will become more apparent from the following detailed description when taken in conjunction with the accompanying drawings.

### BRIEF DESCRIPTION OF THE DRAWINGS

FIGS. 1A˜1D are cross-section views of a conventional method of manufacturing a conductive connection structure ; and

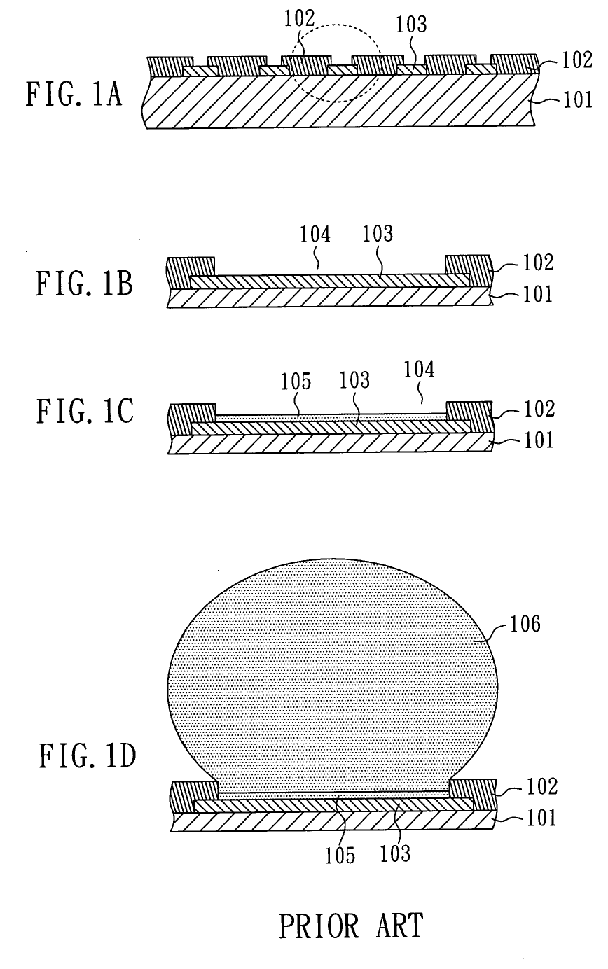

FIGS. 2A˜2E are cross-section views of manufacturing a conductive connection structure of a preferred embodiment.

### DETAILED DESCRIPTION OF THE PREFERRED EMBODIMENT

By the following specific embodiment, the present invention is put into practice. One skilled in the art can easily understand other advantages and efficiency of the present invention through the disclosed content of the specification. Through other different embodiments, the present invention can be carried out or applied. According to different observations and applications, all details of the specification can be modified and changed as not going against the spirit of the present invention.

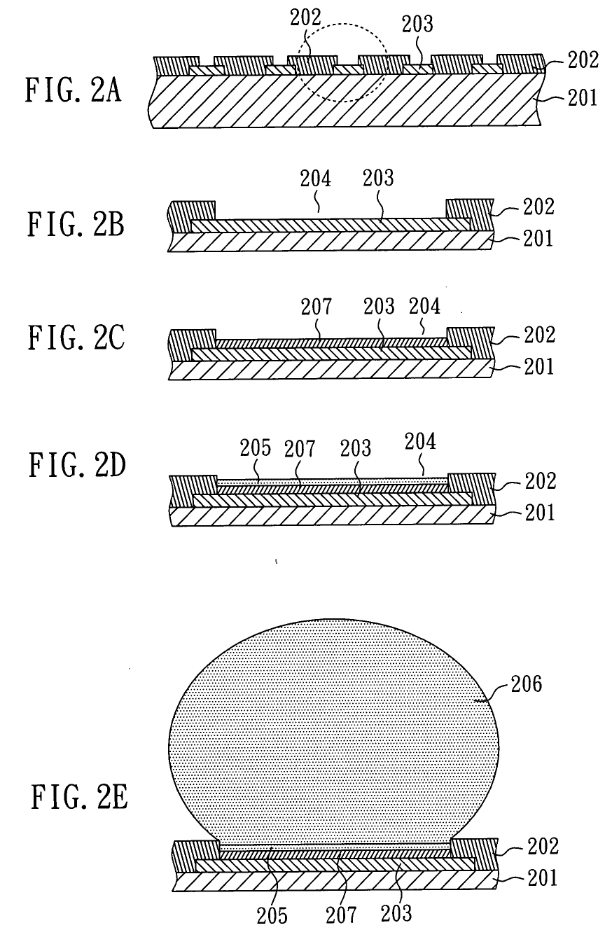

With reference to FIGS. 2A˜2E, a manufacturing method of a conductive connection layer formed on the surface of a circuit board is provided in the present invention.

As shown in FIGS. 2A and 2B, a circuit board 201 and a plurality of connection pads 203 formed on the surface thereof are provided. The connection pads 203 are made of a material selected from the group consisting of copper, nickel, titanium, chromium, tin, or lead. In the present embodiment, the conductive connection pads are 203 composed of conductive copper.

Moreover, a solder mask layer 202 is formed on the surface of the circuit board 201. A plurality of openings 204 corresponding to the surfaces of the conductive pads 203 are formed on the solder mask layer to expose those surfaces.

In FIGS. 2C and 2D, an electroless plating copper layer 207 is formed on the surface of the conductive pads, and thickness thereof is between 7 and 15 μm. Further, an electroless plating adhesive layer 205 is formed on the surface of the electroless plating copper layer 207. The electroless plating adhesive layer 205 is made of a material selected from the group consisting of tin, silver, nickel/gold, titanium, tungsten, titanium/tungsten, chromium, aluminum, or organic solderability preservatives (OSP) etc.

Furthermore, as shown in FIG. 2E, a solder bump 206 is manufactured on the surface of the electroless plating adhesive layer 205. The solder bump 206 consists of one of copper, tin, lead, silver, nickel, gold, or platinum.

With reference to FIG. 2E, the structure made by way of the aforementioned manufacturing method in the present invention is the conductive connection structure formed on the surface of the circuit board. The structure includes: a circuit board; a plurality of conductive pads which are formed on the surface of the circuit board; a solder mask layer which is formed on the surface of the circuit board and forms a plurality of openings corresponding to the conductive pads to expose the surface thereof; an electroless plating copper layer which is formed on the surface of conductive pads; and an electroless plating adhesive layer which is formed on the surface of the electroless plating copper layer.

Because of the potential difference between the tin and copper metal balls, the copper atoms of the copper pads (the conductive pads) diffuse to the solder bump and this causes a metal alloy to be formed and the thickness of the copper pads decreases. The cavity is formed in the interface between copper and tin. By the aforementioned structure and manufacture thereof in the present invention, aforementioned problems are prevented, and the solder bump is fixed then forming a solder ball after reflow soldering.

Although the present invention has been explained in relation to its preferred embodiment, it is to be understood that many other possible modifications and variations can be made without departing from the scope of the invention as hereinafter claimed.

What is claimed is:

1. A conductive connection structure formed on the surface of a circuit board comprising:
a plurality of conductive pads which are formed on the surface of the circuit board;
a solder mask layer which is formed on the surface of the circuit board, and formed with a plurality of openings corresponding to the conductive pads to expose the surface thereof;
an electroless plating copper layer which is formed on the surface of conductive pads ; and
an electroless plating adhesive layer which is formed on the surface of the electroless plating copper layer.

2. The conductive connection structure as claimed in claim 1, wherein a solder bump is formed on the surface of the electroless plating adhesive layer.

3. The conductive connection structure as claimed in claim 1, wherein the conductive pad is made of a material selected from the group consisting of copper, nickel, titanium, chromium, tin, or lead.

4. The conductive connection structure as claimed in claim 1, wherein the solder mask layer is made of photosensitive resin.

5. The conductive connection structure as claimed in claim 1, wherein the thickness of the electroless plating copper layer ranges from 7 to 15 μm.

6. The conductive connection structure as claimed in claim 1, wherein the electroless plating adhesive layer is made of a material selected from the group consisting of tin, silver, nickel/gold, titanium, tungsten, titanium/tungsten, chromium, or aluminum.

7. The conductive connection structure as claimed in claim 2, wherein the solder bump is made of a material selected from the group consisting of copper, tin, lead, silver, nickel, gold, or platinum.

8. A manufacturing method of a conductive connection structure formed on the surface of a circuit board comprising the following steps:
a) providing a circuit board with a solder mask layer and a plurality of conductive pads, wherein a plurality of openings are formed on the solder mask layer to expose the corresponding conductive pads;
b) forming an electroless plating copper layer in the a plurality of openings on the conductive pads ; and
c) forming an electroless plating adhesive layer on the surface of the electroless plating copper layer.

9. The manufacturing method of a conductive connection structure as claimed in claim 8, further comprising a step:
c1) after forming an electroless plating adhesive layer on the surface of the electroless plating copper layer in step c), forming a solder bump on the electroless plating adhesive layer.

10. The manufacturing method of a conductive connection structure as claimed in claim 8, wherein the solder bump is formed through implanting, electroplating, or printing.
